(19) United States
(12) Patent Application Publication
(10) Pub. No.: US 2025/0374580 A1
(43) Pub. Date: Dec. 4, 2025

(54) LOW K INNER SPACER FORMATION BY SELECTIVE PECVD PROCESS IN GATE-ALL-AROUND (GAA) NANOSHEET DEVICE

(71) Applicant: Applied Materials, Inc., Santa Clara, CA (US)

(72) Inventors: Jialiang WANG, Milpitas, CA (US); Sai Hooi YEONG, Cupertino, CA (US); Kashish SHARMA, Santa Clara, CA (US); Abhijit B. MALLICK, Fremont, CA (US)

(21) Appl. No.: 19/220,042

(22) Filed: May 27, 2025

Related U.S. Application Data
(60) Provisional application No. 63/655,586, filed on Jun. 3, 2024.

(51) Int. Cl. H10D 30/01; C23C 16/04; C23C 16/32; C23C 16/40; C23C 16/50; C23C 16/56; H01J 37/32

(52) U.S. Cl. CPC H10D 30/0195; C23C 16/045; C23C 16/32; C23C 16/401; C23C 16/50; C23C 16/56; H01J 37/32357; H01J 2237/3321

(57) ABSTRACT

A method of forming a portion of a gate-all-around field-effect transistor (GAA FET) nanosheet structure includes performing a surface modification process to passivate an exposed surface of a gate spacer formed over a fin-shaped column and exposed surfaces of nanosheet channels, the fin-shaped column comprising a stack of the nanosheet channels and sacrificial layers, and performing a selective deposition process to deposit low-k dielectric material on exposed surfaces of the sacrificial layers, wherein the surface modification process comprises a radical-based plasma process, and the selective deposition process is a plasma enhanced chemical vapor deposition (PECVD) process.

### CROSS-REFERENCE TO RELATED APPLICATIONS

This application claims priority to U.S. Provisional Application Ser. No. 63/655,586 filed Jun. 3, 2024, which is herein incorporated by reference in its entirety.

### BACKGROUND

### Field

Embodiments described herein generally relate to semiconductor device fabrication, and more particularly, to forming a high quality inner spacer in a horizontally stacked gate-all-around field-effect transistor (GAA FET) nanosheet structure.

### Description of the Related Art

In efforts of miniaturization and performance enhancement in semiconductor electronics, complementary metal-oxide semiconductor (CMOS) technology has introduced planar transistors with low costs, low power consumption, and high packing density.

GAA FETs provide design flexibility, low operational voltage, high drive currents, high computational speed, and excellent performance within a smaller footprint area. In a GAA nanosheet structure, a low-k inner spacer with a small dielectric constant is introduced to improve parasitic capacitance between source/drain (S/D) epitaxial layers and metal gates. However, this structure causes a challenge in fabrication of high quality void free inner spacer as the fabrication typically requires a multi-chamber process with a complicated sequence of deposition and etch.

Therefore, there is a need for process integration solutions to form high quality void free low-k inner spacer in a GAA nanosheet structure.

### SUMMARY

Embodiments of the present disclosure provide a method of forming a portion of a gate-all-around field-effect transistor (GAA FET) nanosheet structure. The method includes performing a surface modification process to passivate an exposed surface of a gate spacer formed over a fin-shaped column and exposed surfaces of nanosheet channels, the fin-shaped column comprising a stack of nanosheet channels and sacrificial layers, and performing a selective deposition process to deposit low-k dielectric material on exposed surfaces of the sacrificial layers, wherein the surface modification process comprises a radical-based plasma process, and the selective deposition process is a plasma enhanced chemical vapor deposition (PECVD) process.

Embodiments of the present disclosure also provide a method of forming a portion of a gate-all-around field-effect transistor (GAA FET) nanosheet structure. The method includes performing a selective etch process to remove sacrificial layers from a stack of and form cavities between adjacent nanosheet channels, the stack comprising the nanosheet channels and the sacrificial layers, performing a surface modification process to passivate an exposed surface of a gate spacer formed over a high germanium (Ge) layer on a low Ge layer and exposed surfaces of the nanosheet channels, wherein the low Ge layer is formed on both sides of the stack, and performing a selective deposition process to deposit low-k dielectric material on exposed surfaces of the low Ge layer layers within the cavities, wherein the surface modification process comprises a radical-based plasma process, and the selective deposition process is a plasma enhanced chemical vapor deposition (PECVD) process.

Embodiments of the present disclosure further provide a processing system. The processing system includes a plasma enhanced chemical vapor deposition (PECVD) chamber, and a system controller configured to cause the processing system to perform, in the PECVD chamber, a radical-based plasma process to passivate a surface of a dielectric layer and a surface of a silicon (Si) layer, and perform, in the PECVD chamber, a PECVD process to selectively deposit low-k dielectric material on a surface of a silicon germanium (SiGe) layer and not on the passivated surface of the dielectric layer or the passivated surface of the silicon (Si) layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a processing system, according to one or more embodiments of the present disclosure.

FIGS. 2A and 2B are schematic views of a portion of a semiconductor structure that may form a horizontally stacked gate-all-around field-effect transistor (GAA FET) nanosheet structure, according to one or more embodiments of the present disclosure.

FIG. 3 depicts a process flow diagram of a method of forming an inner spacer in a semiconductor structure that may form a horizontally stacked gate-all-around field-effect transistor (GAA FET) nanosheet structure, according to one embodiment.

FIGS. 4A, 4B, 4C, and 4D are schematic views of a portion of a semiconductor structure corresponding to various states of the method of FIG. 3.

FIG. 5 depicts a process flow diagram of a method of forming an inner spacer in a semiconductor structure that may form a horizontally stacked gate-all-around field-effect transistor (GAA FET) nanosheet structure, according to one embodiment.

FIGS. 6A, 6B, and 6C are schematic views of a portion of a semiconductor structure corresponding to various states of the method of FIG. 5.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for forming high quality inner spacers in a horizontally stacked gate-all-around field-effect transistor (GAA FET) nanosheet structure. The methods include treating surfaces of a gate spacer (e.g., a dielectric layer) with a radical-based plasma and depositing low-k dielectric material selectively on a silicon germanium (SiGe) layer, not on the treated surfaces of the gate spacer, by a plasma enhanced chemical vapor deposition (PECVD) process, in one process chamber. Due to the selective deposition, there is no need for an additional etch process to remove the low-k dielectric material from the surface of the gate spacer. Further, due to the treatment with a radical-based plasma, surfaces of the deposited low-k dielectric material are not damaged and thus void-free high quality spacer layers of the low-k dielectric material can be formed.

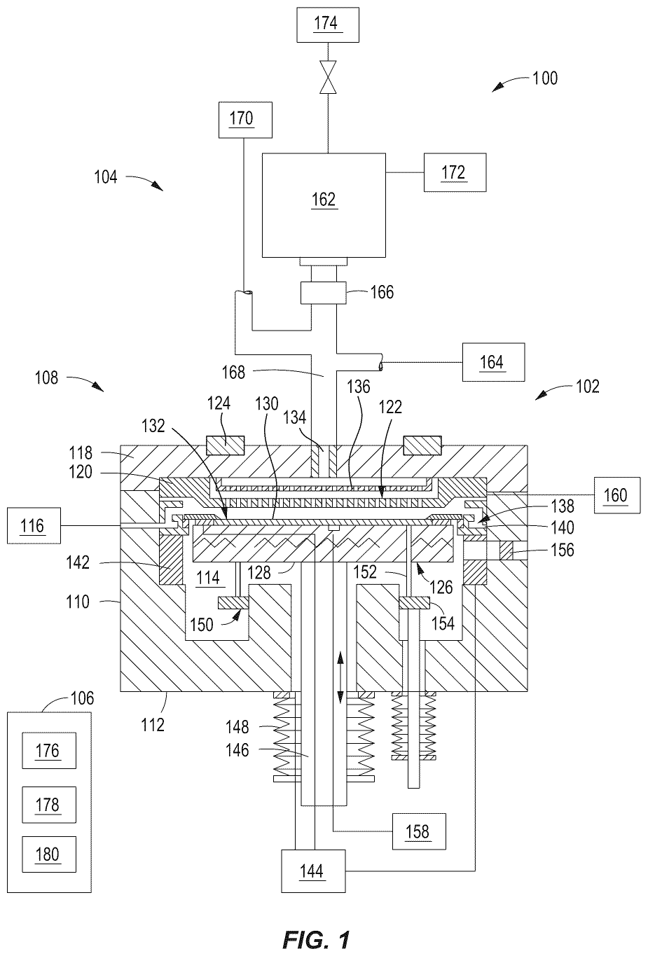

FIG. 1 is a schematic cross sectional view of a processing system 100 configured according to various embodiments of the present disclosure. By way of example, the embodiment of the processing system 100 in FIG. 1 is described in terms of a plasma enhanced chemical vapor deposition (PECVD) system, but any other process chamber may fall within the scope of the embodiments. As shown in FIG. 1, the processing system 100 includes a process chamber 102, a gas delivery system 104 fluidly coupled to the process chamber 102, and a system controller 106. The process chamber 102 includes a chamber lid assembly 108, one or more sidewalls 110, and a chamber base 112, which collectively define a processing volume 114. The processing volume 114 is fluidly coupled to an exhaust 116, such as one or more vacuum pumps, used to maintain the processing volume 114 at sub-atmospheric conditions and to evacuate processing gases and processing by-products therefrom.

The chamber lid assembly 108 includes a lid plate 118 and a showerhead 120 coupled to the lid plate 118 to define a gas distribution volume 122 therewith. Here, the lid plate 118 is maintained at a desired temperature using one or more heaters 124 thermally coupled thereto. The showerhead 120 faces a substrate support assembly 126 disposed in the processing volume 114. As discussed below, the substrate support assembly 126 is configured to move a substrate support 128, and thus a substrate 130 disposed on the substrate support 128, between a raised substrate processing position (as shown) and a lowered substrate transfer position (not shown). When the substrate support assembly 126 is in the raised substrate processing position, the showerhead 120 and the substrate support 128 define a processing region 132.

The gas delivery system 104 is fluidly coupled to the process chamber 102 through a gas inlet 134 that is disposed through the lid plate 118. Processing or cleaning gases delivered, by use of the gas delivery system 104, flow through the gas inlet 134 into the gas distribution volume 122 and are distributed into the processing region 132 through the showerhead 120. In some embodiments, the chamber lid assembly 108 further includes a perforated blocker plate 136 disposed between the gas inlet 134 and the showerhead 120. In those embodiments, gases flowed into the gas distribution volume 122 are first diffused by the blocker plate 136 to, together with the showerhead 120, provide a more uniform or desired distribution of gas flow into the processing region 132.

The processing gases and processing by-products are evacuated radially outward from the processing region 132 through an annular channel 138 that surrounds the processing region 132. The annular channel 138 may be formed in a first annular liner 140 disposed radially inward of the one or more sidewalls 110 (as shown) or may be formed in the one or more sidewalls 110, which are used to protect the interior surfaces. In some embodiments, the process chamber 102 includes one or more second liners 142 to protect the one or more sidewalls 110 or chamber base 112 from corrosive gases and/or undesired material deposition.

In some embodiments, a purge gas source 144 includes a first connection that is in fluid communication with the processing volume 114 so that it can be used to flow a chemically inert purge gas, such as argon (Ar), into a region disposed at a periphery of a substrate and/or beneath the substrate disposed on the substrate support 128, e.g., through the opening in the chamber base 112 surrounding a movable support shaft 146. The purge gas may be used to create a region of positive pressure below the substrate disposed on the substrate support 128 (when compared to the pressure in the processing region 132) during substrate processing. In some configurations, the purge gas is introduced through the chamber base 112 so that it flows upwardly therefrom and around the edges of the substrate support 128 to be evacuated from the processing volume 114 through the annular channel 138. In this configuration, the purge gas reduces undesirable material deposition on surfaces beneath the substrate support 128 by reducing and/or preventing the flow of material precursor gases thereinto.

The substrate support assembly 126 includes the movable support shaft 146 that sealingly extends through the chamber base 112, such as being surrounded by a bellows 148 in the region below the chamber base 112, and the substrate support 128, which is disposed on the movable support shaft 146. To facilitate substrate transfer to and from the substrate support 128, the substrate support assembly 126 includes a lift pin assembly 150 comprising a plurality of lift pins 152 coupled to or disposed in engagement with a lift pin hoop 154. The plurality of lift pins 152 are movably disposed in openings formed through the substrate support 128.

The substrate 130 is transferred to and from the substrate support 128 through a door 156, e.g., a slit valve disposed in one of the one or more sidewalls 110. Here, one or more openings in a region surrounding the door 156, e.g., openings in a door housing, are fluidly coupled to the purge gas source 144, e.g., an argon (Ar) gas source. The purge gas is used to prevent processing and cleaning gases from contacting and/or degrading a seal surrounding the door, thus extending the useful lifetime thereof.

The substrate support 128 is configured for vacuum chucking where the substrate 130 is secured to the substrate support 128 by applying a vacuum to an interface between the substrate 130 and the substrate receiving surface, such as with a vacuum source 158.

The showerhead 120 may be electrically coupled to a first power supply 160, such as an RF power supply, which supplies power to form and maintain a capacitively coupled plasma using processing gases flowed into the processing region 132 through the showerhead 120.

Generally, the gas delivery system 104 includes one or more remote plasma sources, here a radical generator 162, and a deposition gas source 164 fluidly coupled to the chamber lid assembly 108. The gas delivery system 104 further includes an isolation valve 166, disposed between the radical generator 162 and the lid plate 118, which may be used to fluidly isolate the radical generator 162 from the process chamber 102 and from other radical generators, if applicable (not shown). Deposition precursors are delivered from the deposition gas source 164 to the process chamber 102 using a conduit system 168. The gas delivery system 104 further includes a purge gas source 170 to purge the conduit system 168.

The radical generator 162 is coupled to a power supply 172, such as a radio frequency (RF) power supply. The power supply 172 is used to ignite and maintain a plasma that is delivered to the plasma chamber volumes using gases provided from a corresponding gas source 174 fluidly coupled thereto.

Operation of the processing system 100 is facilitated by the system controller 106. The system controller 106 includes a programmable central processing unit (CPU) 176, which is operable with a memory 178 (e.g., non-volatile memory) and support circuits 180. The CPU 176 is one of any form of general-purpose computer processor used in an industrial setting, such as a programmable logic controller (PLC), for controlling various chamber components and sub-processors. The memory 178, coupled to the CPU 176, facilitates the operation of the process chamber 102. The support circuits 180 are conventionally coupled to the CPU 176 and comprise cache, clock circuits, input/output subsystems, power supplies, and the like, and combinations thereof coupled to the various components of the processing system 100 to facilitate control of substrate processing operations therewith.

The instructions in the memory 178 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

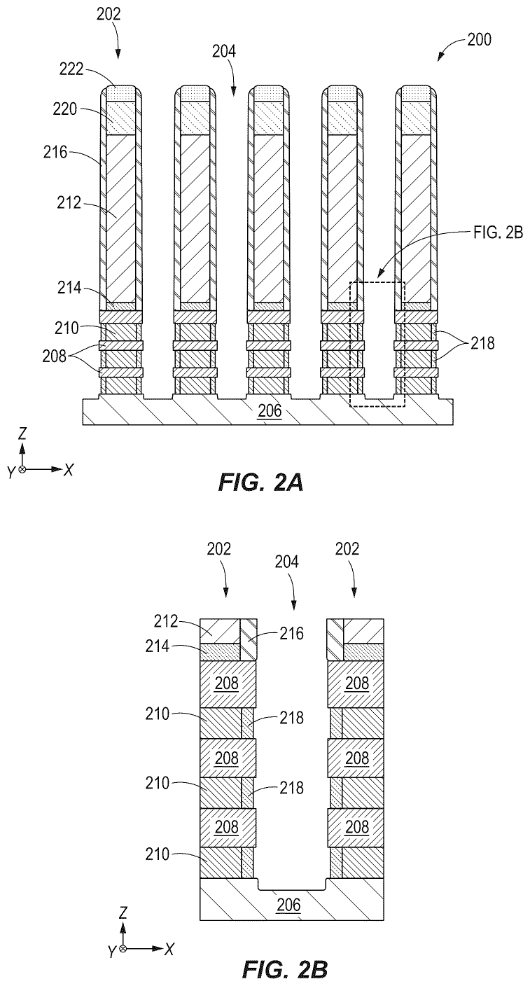

FIG. 2A is a cross-sectional view of a portion of a semiconductor structure 200 that may form a horizontally stacked gate-all-around field-effect transistor (GAA FET) nanosheet structure, according to one or more embodiments of the present disclosure. FIG. 2B is an enlarged view of a portion of the semiconductor structure 200.

As shown in FIGS. 2A and 2B, the semiconductor structure 200 includes fin-shaped columns 202, extending in the Z direction that are isolated from adjacent fin-shaped columns 202 in the X direction by a source/drain (S/D) recess 204, on a substrate 206. Each fin-shaped column 202 includes a stack of nanosheet channels 208 and sacrificial layers 210, and interfaces with a dummy gate 212 via a dummy oxide layer 214. The dummy gate 212 is covered by a gate spacer 216. The semiconductor structure 200 further includes inner spacers 218 disposed on both sides of the sacrificial layers 210 in the X direction. Inner spacers 218 are formed to isolate the sacrificial layers 210 from S/D epi layers to be formed within the S/D recesses 204.

The fin-shaped columns 202 may each have a width in the X direction of between about 6 nm and about 200 nm. A pitch between adjacent dummy gates 212 in the X direction may be between about 40 nm and about 80 nm. As shown, the fin-shaped columns 202 each include three pairs of the nanosheet channels 208 and the sacrificial layers 210. However, in some embodiments, the fin-shaped columns 202 each include between 3 and 8 pairs of the nanosheet channels 208 and the sacrificial layers 210.

The nanosheet channels 208 may be formed of silicon (Si), germanium (Ge), silicon germanium (SiGe), or indium gallium zinc oxide (IGZO), each having a thickness of between about 3 nm and about 10 nm. The sacrificial layers 210 may be formed of silicon germanium (SiGe) with a ratio of germanium (Ge) ranging between about 10% and about 60%. The sacrificial layers 210 may each have a thickness of between about 4 nm and about 20 nm, for example, about 12 nm.

The term “substrate” as used herein refers to a layer of material that serves as a basis for subsequent processing operations and includes a surface to be cleaned. The substrate 206 may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The dummy gates 212 may be formed of polycrystalline silicon (Si). The dummy oxide layer 214 may be formed of silicon oxide (SiO₂).

The gate spacers 216 may be formed of dielectric material, such as silicon nitride (Si₃N₄), silicon oxycarbide (SiOC), silicon oxy-carbon-nitride (SiOCN), or silicon carbon nitride (SiCN).

The inner spacer 218 may be formed of low-k dielectric material that has etch selectivity from the gate spacer 216, such as silicon oxycarbide (SiOC), silicon nitride (Si₃N₄) silicon boron carbon nitride (SiBCN), silicon oxy-carbon-nitride (SiOCN), organosilicate glass (SiCOH), or any combination thereof, having a thickness of between about 3 nm and about 10 nm, for example, between about 6 nm and about 7 nm.

In FIG. 2A, a hard mask 220 and a mask 222 used to pattern the dummy gates 212 used to pattern the fin-shaped columns 202 during fabrication are shown. The hard mask 220 may be formed of silicon nitride (Si₃N₄). The mask 222 may be formed of silicon oxide (SiO₂).

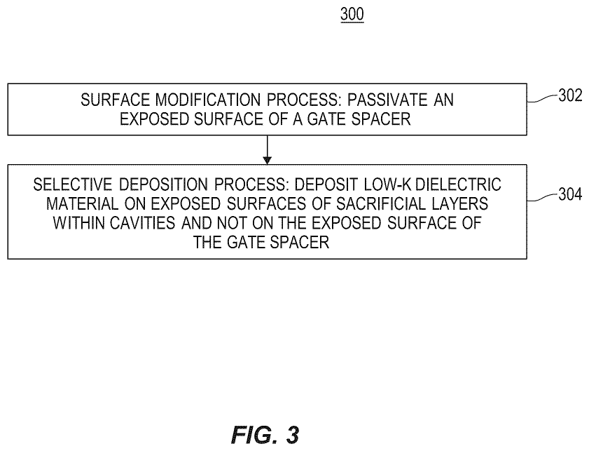

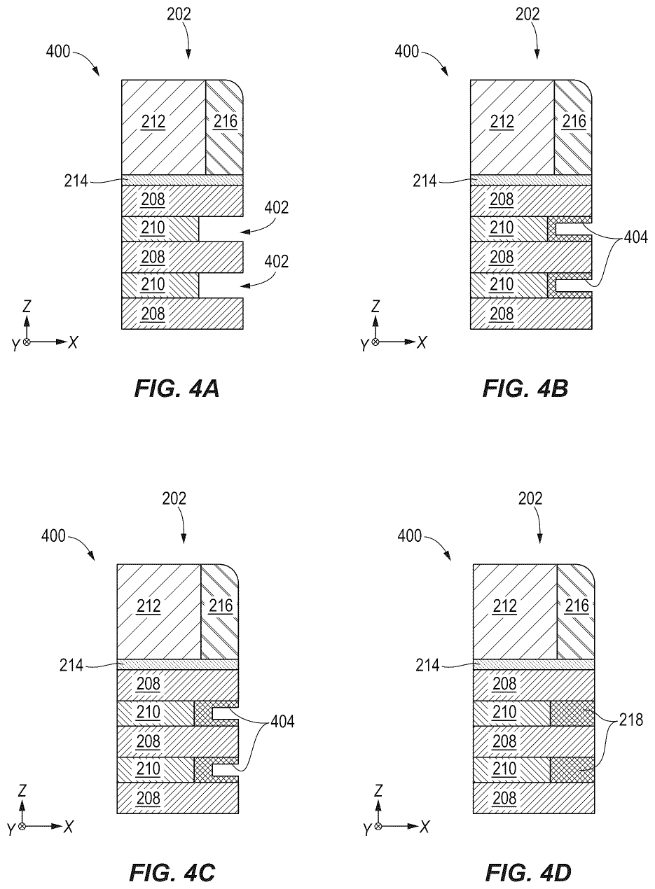

FIG. 3 depicts a process flow diagram of a method 300 of forming an inner spacer in a semiconductor structure 400 that may be the semiconductor structure 200 forming a portion of a horizontally stacked gate-all-around field-effect transistor (GAA FET) nanosheet structure, according to one or more embodiments of the present disclosure. In the method 300, a gate spacer is formed first in the process. FIGS. 4A, 4B, 4C, and 4D are cross-sectional views of a portion of the semiconductor structure 400 corresponding to various states of the method 300. It should be understood that FIGS. 4A, 4B, 4C, and 4D illustrate only partial schematic views of the semiconductor structure 400, and the semiconductor structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or have been rearranged in another desirable order, fall within the scope of the embodiments of the disclosure provided herein.

The semiconductor structure 400 shown in FIG. 4A may be formed by epitaxially growing a stack of alternating nanosheet channels 208 and sacrificial layers 210 on a substrate, and patterning the stack to define fin-shaped columns 202 extending in the Z direction. Each of the sacrificial layers 210 is recessed and a cavity 402 is formed between adjacent nanosheet channels 208. Dummy gates 212 are formed and patterned using a hard mask 220 and a mask 222 (shown in FIG. 2A), and interface with the fin-shaped columns 202 via a dummy oxide layer 214. A gate spacer 216 is formed over the dummy gate 212 in the X direction.

As shown, the fin-shaped columns 202 each include three nanosheet channels 208 and two sacrificial layers 210. However, in some embodiments, the fin-shaped columns 202 each include between 3 and 8 pairs of the nanosheet channels 208 and the sacrificial layers 210.

The nanosheet channels 208 may be formed of silicon (Si), germanium (Ge), silicon germanium (SiGe), or indium gallium zinc oxide (IGZO), each having a thickness of between about 3 nm and about 13 nm, for example, about 8 nm. The sacrificial layers 210 may be formed of silicon germanium (SiGe) with a ratio of germanium (Ge) ranging between about 10% and about 60%. The sacrificial layers 210 may each have a thickness of between about 4 nm and about 20 nm, for example, about 12 nm. The cavities 402 may each have a depth in the X direction of between about 10 nm and about 20 nm.

The dummy oxide layer 214 may be formed of silicon oxide (SiO₂). The gate spacers 216 may be formed of dielectric material, such as silicon nitride (Si₃N₄), silicon oxycarbide (SiOC), silicon oxy-carbon-nitride (SiOCN), or silicon carbon nitride (SiCN).

The method 300 begins with block 302, in which a surface modification process is performed to passivate an exposed surface of the gate spacer 216 and exposed surfaces of the nanosheet channels 208 in a plasma enhanced chemical vapor deposition (PECVD) chamber, such as the process chamber 102 depicted in FIG. 1. The surface modification process may include a radical-based plasma process, in which the exposed surface of the gate spacer 216 is exposed to a plasma generated remotely from a process gas including hydrogen (H₂), a mixture of hydrogen (H₂) and nitrogen (N₂), a mixture of hydrogen (H₂) and nitrogen (NH₂), a mixture of hydrogen (H₂) and methane (CH₄), a mixture of hydrogen (H₂) and noble gas (e.g., helium (He), argon (Ar)), or any combination thereof. Due to minimal exposure to high-energy ions, there is less damage on exposed surfaces of the semiconductor structure 400, preserving incoming chemical structures of the exposed surfaces.

In block 304, a selective deposition process is performed to deposit low-k dielectric material 404 on exposed surfaces of the sacrificial layers 210 within the cavities 402 and not on the exposed surface of the gate spacer 216 or exposed surfaces of the nanosheet channels 208, as shown in FIG. 4B. The selective deposition process is performed by a PECVD process in the same PECVD chamber in which the surface modification process in block 302 is performed.

In the deposition process, low-k dielectric material 404, such as SiOC, is deposited by a PECVD process using silicon-containing precursor. The selectivity in the selective deposition may arise from differences in nucleation of the low-k dielectric material 404 on the surfaces of the sacrificial layers 210 (e.g., silicon germanium (SiGe)) and the passivated surface of the gate spacer 216 (e.g., silicon nitride (Si₃N₄)) or the passivated surfaces of the nanosheet channels 208 (e.g., silicon (Si)). The nucleation may occur at a faster rate on the sacrificial layers 210 (e.g., silicon germanium (SiGe)) than on the passivated surface of the gate spacer 216 (e.g., silicon nitride (Si₃N₄)) or the passivated surfaces of the nanosheet channels 208 (e.g., silicon (Si)) due to termination of silicon (Si) with hydrogen, and thus the low-k dielectric material 404 may be formed selectively on the sacrificial layers 210 (e.g., silicon germanium (SiGe)).

The silicon-containing precursor may be 1,3-Diethoxy-1,3-dimethyl-1,3-disilacyclobutane (AME), or organosilicon-precursor, such as bis(trimethylsilyl) methane (BTMSM, [(CH₃)₃Si]₂CH₂), methyltriethoxysilane (MTES, CH₃Si(OC₂H₅)₃), dimethoxydimethylsilane (DMDMDS, Si(OCH₃)₂(CH₃)₂), methyltrimethoxysilane (MTMS, CH₃Si(OCH₃)₃), trimethylsilane (3MS), tetramethylcyclotetrasiloxane (TMCTS), diethoxymethylsilane (DEMS), or alpha-terpinene (ATRP).

Since the incoming chemical structures of the exposed surfaces of the semiconductor structure 400 are preserved in the surface modification process with radical-based plasma in block 302, the surface of the gate spacer 216 may incorporate methyl (CH₃) in the silicon-oxygen backbone. These methyl groups increase porosity of the low-k dielectric material 404, which lowers the dielectric constant, since air has the lowest dielectric constant. Further, the radical-based plasma process minimizes damages to surfaces of the formed low-k dielectric material 404. Thus, this process can achieve void-free cavity fill.

The selective deposition may be performed at a flow rate of between about 100 sccm and about 2000 sccm, at a chamber pressure of between about 0.5 Torr and about 10 Torr, at an RF power of between about 500 W and about 6000 W.

A cycle of the surface modification process in block 302 and the selective deposition in block 304 may be continued as needed to fill the cavities 402 with the low-k dielectric material 404 to form an inner spacer 218 within the cavities 402, as shown in FIGS. 4C and 4D.

The method 300 is a one-chamber solution, performed in-situ in a PE-CVD chamber. Since there is no deposition of low-k dielectric material 404 on the surface of the gate spacer 216, there is no need for an additional process to etch back the low-k dielectric material 404 on the gate spacer 216, which would damage surfaces of the semiconductor structure 400.

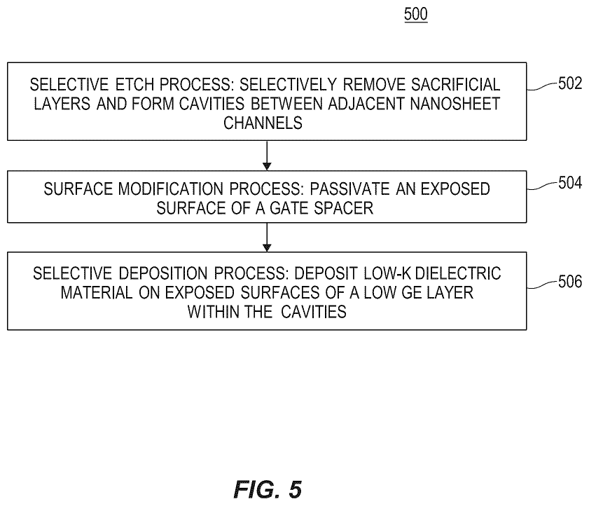

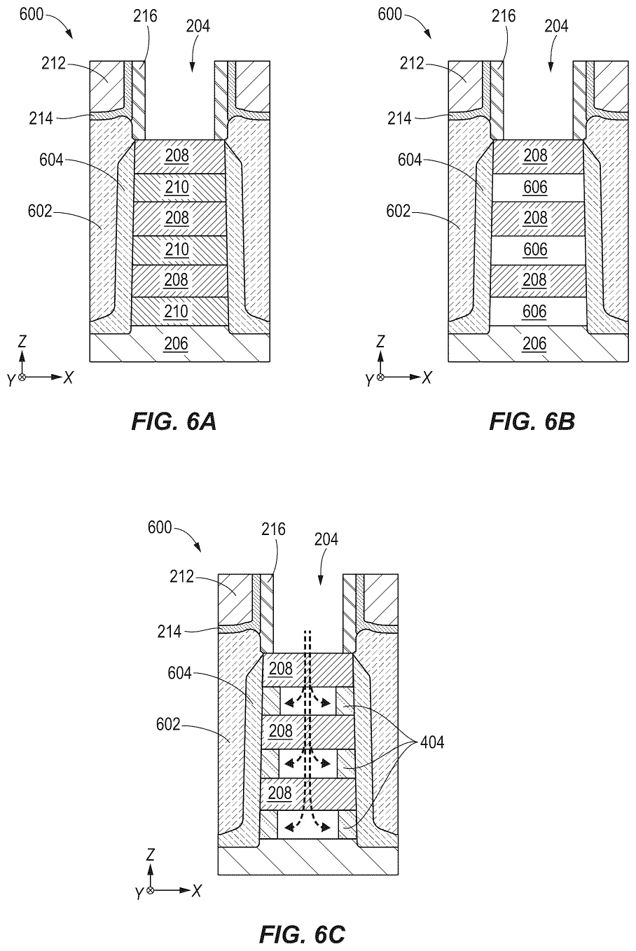

FIG. 5 depicts a process flow diagram of a method 500 of forming an inner spacer in a semiconductor structure 600 that may be the semiconductor structure 200 forming a portion of a horizontally stacked gate-all-around field-effect transistor (GAA FET) nanosheet structure, according to one or more embodiments of the present disclosure. In this method 500, a gate spacer is formed last in the process. FIGS. 6A, 6B, and 6C are cross-sectional views of a portion of the semiconductor structure 600 corresponding to various states of the method 500. It should be understood that FIGS. 6A, 6B, and 6C illustrate only partial schematic views of the semiconductor structure 600, and the semiconductor structure 600 may contain any number of transistor sections and additional materials having aspects as illustrated in the figures. It should also be noted that although the method illustrated in FIG. 5 is described sequentially, other process sequences that include one or more operations that have been omitted and/or added, and/or has been rearranged in another desirable order, fall within the scope of the embodiments of the disclosure provided herein.

The semiconductor structure 600 shown in FIG. 6A may be formed by epitaxially growing a stack of alternating nanosheet channels 208 and sacrificial layers 210 on a substrate 206. The semiconductor structure 600 further includes a high germanium (Ge) layer 602 on a low Ge layer 604 on both sides of the stack in the X direction. Dummy gates 212 are formed and patterned using a hard mask 220 and a mask 222 (shown in FIG. 2A), and interface with the high Ge layer 602 via a dummy oxide layer 214. A gate spacer 216 is formed over the dummy gate 212 in the X direction.

As shown, the stack includes three nanosheet channels 208 and three sacrificial layers 210. However, in some embodiments, the fin-shaped columns 202 each include between 3 and 8 pairs of the nanosheet channels 208 and the sacrificial layers 210.

The nanosheet channels 208 may be formed of silicon (Si), germanium (Ge), silicon germanium (SiGe), or indium gallium zinc oxide (IGZO), each having a thickness of between about 3 nm and about 10 nm. The sacrificial layers 210 may be formed of silicon germanium (SiGe) with a ratio of germanium (Ge) ranging between about 10% and about 60%, for example, about 25%. The sacrificial layers 210 may each have a thickness of between about 4 nm and about 20 nm, for example, about 12 nm. The high Ge layer 602 may be formed of silicon germanium (SiGe) with a ratio of germanium (Ge) ranging between about 25% and about 50%. The low Ge layer 604 may be formed of silicon germanium (SiGe) with a ratio of germanium (Ge) ranging between about 5% and about 15%, for example, about 10%.

The dummy oxide layer 214 may be formed of silicon oxide (SiO₂). The gate spacers 216 may be formed of low-k dielectric material, such as silicon nitride (Si₃N₄), silicon oxycarbide (SiOC), silicon oxy-carbon-nitride (SiOCN), or silicon carbon nitride (SiCN).

The method 500 begins with block 502, in which a selective etch process is performed to selectively remove the sacrificial layers 210 and form cavities 606 between adjacent nanosheet channels 208, as shown in FIG. 6B.

In block 504, a surface modification process is performed to passivate an exposed surface of the gate spacer 216 and exposed surfaces of the nanosheet channels 208 in a plasma enhanced chemical vapor deposition (PECVD) chamber, such as the process chamber 102 depicted in FIG. 1. The surface modification process in block 504 is similar to or the same as the surface modification process in block 302.

In block 506, a selective deposition process is performed to deposit low-k dielectric material 404 on exposed surfaces of the low Ge layer 604 within the cavities 606. The selective deposition process in block 506 is similar to or the same as the selective deposition process in block 304.

A cycle of the surface modification process in block 504 and the selective deposition in block 506 may be continued as needed to fill the cavities 402 with the low-k dielectric material 404 to form an inner spacer 218 of a desired thickness of between about 3 nm and about 8 nm, for example, between about 6 nm and about 7 nm.

The embodiments described herein provide methods for forming high quality inner spacers in a horizontally stacked gate-all-around field-effect transistor (GAA FET) nanosheet structure. The methods include treating surfaces of a gate spacer (e.g., a dielectric layer) with a radical-based plasma and depositing low-k dielectric material selectively on a silicon germanium (SiGe) layer, not on the treated surfaces of the gate spacer, by a plasma enhanced chemical vapor deposition (PECVD) process, in one process chamber. Due to the selective deposition, there is no need for an additional etch process to remove the low-k dielectric material from the surface of the gate spacer. Further, due to the treatment with a radical-based plasma, surfaces of the deposited low-k dielectric material are not damaged and thus void-free high quality spacer layers of the low-k dielectric material can be formed.

While the foregoing is directed to embodiments of the present disclosure, other and further embodiments of the disclosure may be devised without departing from the basic scope thereof, and the scope thereof is determined by the claims that follow.

1. A method of forming a portion of a gate-all-around field-effect transistor (GAA FET) nanosheet structure, comprising:
performing a surface modification process to passivate an exposed surface of a gate spacer formed over a fin-shaped column and exposed surfaces of nanosheet channels, the fin-shaped column comprising a stack of the nanosheet channels and sacrificial layers; and
performing a selective deposition process to deposit low-k dielectric material on exposed surfaces of the sacrificial layers, wherein:
the surface modification process comprises a radical-based plasma process, and
the selective deposition process is a plasma enhanced chemical vapor deposition (PECVD) process.

2. The method of claim 1, wherein the surface modification process and the selective deposition process are performed in a same process chamber.

3. The method of claim 1, wherein the low-k dielectric material comprises silicon oxycarbide (SiOC).

4. The method of claim 1, wherein the PECVD process uses silicon-containing precursor comprising 1,3-Diethoxy-1,3-dimethyl-1,3-disilacyclobutane (AME), bis(trimethylsilyl) methane (BTMSM, [(CH₃)₃Si]₂CH₂), methyltriethoxysilane (MTES, CH₃Si(OC₂H₅)₃), dimethoxydimethylsilane (DMDMDS, Si(OCH₃)₂(CH₃)₂), methyltrimethoxysilane (MTMS, CH₃Si(OCH₃)₃), trimethylsilane (3MS), tetramethylcyclotetrasiloxane (TMCTS), diethoxymethylsilane (DEMS), or alpha-terpinene (ATRP).

5. The method of claim 1, wherein the gate spacer comprises nitride (Si₃N₄), silicon oxycarbide (SiOC), silicon oxy-carbon-nitride (SiOCN), or silicon carbon nitride (SiCN).

6. The method of claim 1, wherein:
the nanosheet channels comprises silicon (Si), each having a thickness of between 3 nm and 13 nm, and
the sacrificial layers comprise silicon germanium (SiGe) with a ratio of germanium (Ge) ranging between 10% and 60%, each having a thickness of between 4 nm and 20 nm.

7. The method of claim 1, wherein in the surface modification process, the exposed surface of the gate spacer is exposed to a plasma generated remotely from a process gas including hydrogen (H₂).

8. A method of forming a portion of a gate-all-around field-effect transistor (GAA FET) nanosheet structure, comprising:
performing a selective etch process to remove sacrificial layers from a stack and form cavities between adjacent nanosheet channels, the stack comprising the nanosheet channels and the sacrificial layers;
performing a surface modification process to passivate an exposed surface of a gate spacer formed over a high germanium (Ge) layer on a low Ge layer and exposed surfaces of the nanosheet channels, wherein the low Ge layer is formed on both sides of the stack; and
performing a selective deposition process to deposit low-k dielectric material on exposed surfaces of the low Ge layer layers within the cavities, wherein:
the surface modification process comprises a radical-based plasma process, and
the selective deposition process is a plasma enhanced chemical vapor deposition (PECVD) process.

9. The method of claim 8, wherein the surface modification process and the selective deposition process are performed in a same process chamber.

10. The method of claim 8, wherein the low-k dielectric material comprises silicon oxycarbide (SiOC).

11. The method of claim 8, wherein the PECVD process uses silicon-containing precursor comprising 1,3-Diethoxy-1,3-dimethyl-1,3-disilacyclobutane (AME), bis(trimethylsilyl) methane (BTMSM, [(CH₃)₃Si]₂CH₂), methyltriethoxysilane (MTES, CH₃Si(OC₂H₅)₃), dimethoxydimethylsilane (DMDMDS, Si(OCH₃)₂(CH₃)₂), methyltrimethoxysilane (MTMS, CH₃Si(OCH₃)₃), trimethylsilane (3MS), tetramethylcyclotetrasiloxane (TMCTS), diethoxymethylsilane (DEMS), or alpha-terpinene (ATRP).

12. The method of claim 8, wherein the gate spacer comprises nitride (Si₃N₄), silicon oxycarbide (SiOC), silicon oxy-carbon-nitride (SiOCN), or silicon carbon nitride (SiCN).

13. The method of claim 8, wherein:
the nanosheet channels comprises silicon (Si), each having a thickness of between 3 nm and 13 nm, and
the sacrificial layers comprise silicon germanium (SiGe) with a ratio of germanium (Ge) ranging between 10% and 60%, each having a thickness of between 4 nm and 20 nm.

14. The method of claim 8, wherein:
the high Ge layer comprises silicon germanium (SiGe) with a ratio of germanium (Ge) ranging between 25% and 50%, and
the low Ge layer comprises silicon germanium (SiGe) with a ratio of germanium (Ge) ranging between 5% and 15%.

15. The method of claim 8, wherein in the surface modification process, the exposed surface of the gate spacer is exposed to a plasma generated remotely from a process gas including hydrogen (H₂).

16. A processing system, comprising:
a plasma enhanced chemical vapor deposition (PECVD) chamber; and
a system controller configured to cause the processing system to:
perform, in the PECVD chamber, a radical-based plasma process to passivate a surface of a dielectric layer and a surface of a silicon (Si) layer; and
perform, in the PECVD chamber, a PECVD process to selectively deposit low-k dielectric material on a surface of a silicon germanium (SiGe) layer and not on the passivated surface of the dielectric layer or the passivated surface of the Si layer.

17. The processing system of claim 16, wherein the dielectric layer comprises nitride (Si₃N₄), silicon oxycarbide (SiOC), silicon oxy-carbon-nitride (SiOCN), or silicon carbon nitride (SiCN).

18. The processing system of claim 16, wherein the SiGe layer comprises silicon germanium (SiGe) with a ratio of germanium (Ge) ranging between 10% and 60%.

19. The processing system of claim 16, wherein the low-k dielectric material comprises silicon oxycarbide (SiOC).

20. The processing system of claim 16, wherein the PECVD process uses silicon-containing precursor comprising 1,3-Diethoxy-1,3-dimethyl-1,3-disilacyclobutane (AME), bis(trimethylsilyl) methane (BTMSM, [(CH₃)₃Si]₂CH₂), methyltriethoxysilane (MTES, CH₃Si(OC₂H₅)₃), dimethoxydimethylsilane (DMDMDS, Si(OCH₃)₂(CH₃)₂), methyltrimethoxysilane (MTMS, CH₃Si(OCH₃)₃), trimethylsilane (3MS), tetramethylcyclotetrasiloxane (TMCTS), diethoxymethylsilane (DEMS), or alpha-terpinene (ATRP).
